(19) United States
(12) Patent Application Publication
(10) Pub. No.: US 2026/0005178 A1
(43) Pub. Date: Jan. 1, 2026

(54) SEMICONDUCTOR PACKAGE

(71) Applicant: Samsung Electronics Co., Ltd., Suwon-si (KR)

(72) Inventors: Dongwon KANG, Suwon-si (KR); Changyeon SONG, Suwon-si (KR); Jae-Ean LEE, Suwon-si (KR)

(73) Assignee: Samsung Electronics Co., Ltd., Suwon-si (KR)

(21) Appl. No.: 19/050,250

(22) Filed: Feb. 11, 2025

(30) Foreign Application Priority Data
Jun. 27, 2024 (KR) 10-2024-0084292

(51) Int. Cl. H01L 23/00; H01L 23/31; H01L 23/498; H01L 25/18; H10D 1/60

(52) U.S. Cl. CPC H01L 24/24; H01L 23/49822; H01L 25/18; H01L 23/3128; H01L 2224/24265; H01L 2224/24997; H10D 1/60

(57) ABSTRACT

A semiconductor package that includes a first redistribution substrate including a first surface and a second surface facing the first surface; a semiconductor chip on the first surface; an electronic element on the second surface; and an underfill pattern between the electronic element and the second surface. The first redistribution substrate includes a first insulating layer, and an insulating pattern and a dam structure both on the first insulating layer. The dam structure is spaced apart from the electronic element in a first direction parallel to the second surface. The insulating pattern includes an insulating material different from that of the first insulating layer. The insulating pattern is in contact with the first insulating layer and the underfill pattern.

### CROSS-REFERENCE TO RELATED APPLICATIONS

This U.S. non-provisional patent application claims priority under 35 U.S.C. § 119 to Korean Patent Application No. 10-2024-0084292 filed on Jun. 27, 2024, in the Korean Intellectual Property Office, the entire contents of which are hereby incorporated by reference.

### BACKGROUND

The inventive concepts relate to semiconductor packages.

A semiconductor package may be provided to implement an integrated circuit chip for use in electronic products. Typically, the semiconductor package includes a semiconductor chip mounted on a printed circuit board and bonding wires or bumps may be used to electrically connect the semiconductor chip to the printed circuit board. With the development of electronic industry, various studies have been conducted to improve reliability and/or durability of semiconductor packages.

### SUMMARY

Object of the inventive concepts are to provide a structure of a semiconductor package with improved reliability and/or durability.

Some example embodiments of the inventive concepts provide a semiconductor package that includes a first redistribution substrate including a first surface and a second surface facing the first surface; a semiconductor chip on the first surface; an electronic element on the second surface; and an underfill pattern between the electronic element and the second surface. The first redistribution substrate includes a first insulating layer, and an insulating pattern and a dam structure both on the first insulating layer. The dam structure is spaced apart from the electronic element in a first direction parallel to the second surface. The insulating pattern includes an insulating material different than an insulating material of the first insulating layer. The insulating pattern is in contact with the first insulating layer and the underfill pattern.

Some example embodiments of the inventive concepts further provide a semiconductor package that includes a redistribution substrate including a first surface and a second surface facing the first surface; a semiconductor chip on the first surface; an electronic element on the second surface; and an underfill pattern between the electronic element and the second surface. The redistribution substrate includes a first insulating layer; a redistribution pattern in the first insulating layer; a second insulating layer on the first insulating layer and the redistribution pattern; and an insulating pattern on the second insulating layer. The electronic element overlaps the insulating pattern in a vertical direction. The second insulating layer has a first surface roughness. The insulating pattern has a second surface roughness. The second surface roughness is lower than the first surface roughness. The underfill pattern is in contact with the insulating pattern.

Some example embodiments of the inventive concepts still further provide a semiconductor package that includes a first redistribution substrate including a first surface and a second surface facing the first surface; a connection substrate on the first surface, the connection substrate defining a hole therein; a semiconductor chip in the hole; a molding layer filling the hole and covering the semiconductor chip; a capacitor on the second surface; an underfill pattern between the capacitor and the second surface; and a second redistribution substrate on the molding layer and the connection substrate. The first redistribution substrate includes a first insulating layer; a redistribution pattern in the first insulating layer; a second insulating layer on the first insulating layer and the redistribution pattern; connection pads and an insulating pattern both on the second insulating layer; and a dam structure surrounding the connection pads and the insulating pattern. The insulating pattern is between the connection pads. The insulating pattern includes an insulating material different than an insulating material of the second insulating layer. The insulating pattern includes a photosensitive insulating material. The underfill pattern is in contact with the insulating pattern.

### BRIEF DESCRIPTION OF THE DRAWINGS

Some example embodiments will be more clearly understood from the following brief description taken in conjunction with the accompanying drawings. The accompanying drawings represent non-limiting, example embodiments as described herein.

FIG. 1 is a cross-sectional view showing a semiconductor package according to some example embodiments of the inventive concepts.

FIG. 2 is a plan view showing a lower surface of a semiconductor package according to some example embodiments of the inventive concepts.

FIG. 3 is a cross-sectional view taken along line A-A′ of FIG. 2.

FIG. 4 is a cross-sectional view taken along line B-B′ of FIG. 2.

FIG. 5 is a plan view showing a semiconductor package according to some example embodiments of the inventive concepts.

FIG. 6 is a cross-sectional view taken along line A-A′ of FIG. 3.

FIGS. 7A, 7B, 7C and 7D are cross-sectional views illustrating a process for manufacturing a semiconductor package according to some example embodiments of the inventive concepts.

FIG. 8 illustrates a semiconductor package according to a comparative example.

FIG. 9 is a cross-sectional view illustrating a semiconductor package according to some example embodiments of the inventive concepts.

FIGS. 10A, 10B, 10C, 10D and 10E are cross-sectional views illustrating a process for manufacturing a semiconductor package according to some example embodiments of the inventive concepts.

### DETAILED DESCRIPTION

In this specification, the same reference numerals may refer to the same components throughout the specification. A semiconductor package according to the inventive concepts is described.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

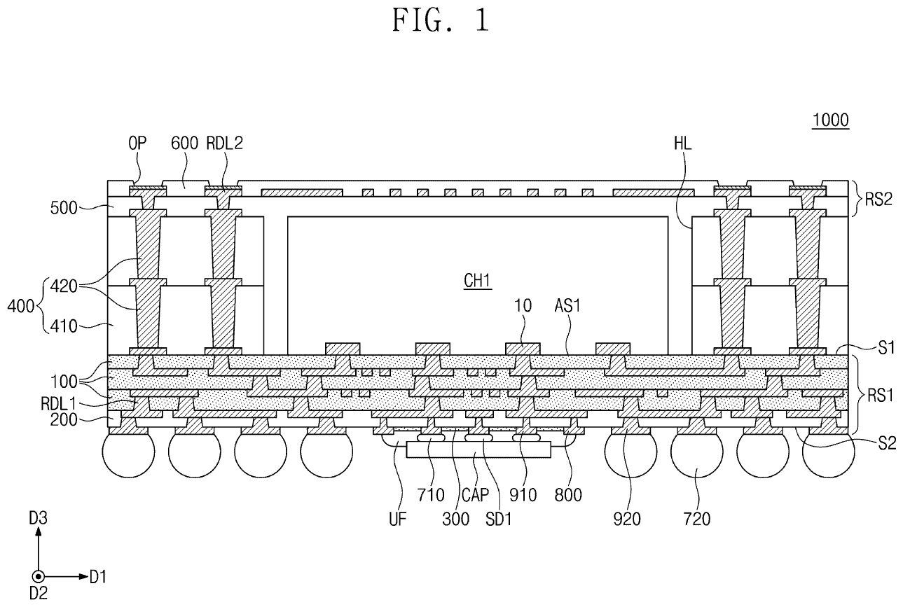

FIG. 1 is a cross-sectional view showing a semiconductor package according to some example embodiments of the inventive concepts.

Referring to FIG. 1, a semiconductor package 1000 may include a connection substrate 400, a semiconductor chip CH1, a molding layer 500, a first redistribution substrate RS1, a second redistribution substrate RS2, an electronic element CAP, and an underfill pattern UF.

The connection substrate 400 may be an embedded trace substrate. The connection substrate 400 may include base layers 410 and conductive structures 420. The base layers 410 may include an insulating material. For example, the base layers 410 may include a carbon-based material, a ceramic, or a polymer. The conductive structure 420 may include wiring lines and wiring vias connecting the wiring lines. The conductive structure 420 may include a metal. The conductive structure 420 may include at least one selected from, for example, copper, aluminum, gold, lead, stainless steel, silver, iron, and alloys thereof. The connection substrate 400 may include a hole HL in the center thereof. For example, the connection substrate 400 may define a hole HL therein in the center of the connection substrate 400.

The semiconductor chip CH1 may be disposed in the hole HL of the connection substrate 400. The semiconductor chip CH1 may include either a logic chip or a memory chip. The semiconductor chip CH1 may be either a DRAM, an SRAM, a NAND-FLASH, a central processing unit (CPU), a graphics processing unit (GPU), and an application specific integrated circuit (ASIC). The semiconductor chip CH1 may be disposed laterally spaced from the connection substrate 400.

The molding layer 500 may fill a space between the hole HL of the connection substrate 400 and a side surface of the semiconductor chip CH1. The molding layer 500 may cover an upper surface of the connection substrate 400 and an upper surface of the semiconductor chip CH1. The molding layer 500 may include an epoxy-based compound. According to some example embodiments, the molding layer 500 may be formed from Ajinomoto build-up film (ABF).

The first redistribution substrate RS1 may be disposed under the connection substrate 400, the semiconductor chip CH1, and the molding layer 500. An active surface AS1 on which a chip pad 10 of the semiconductor chip CH1 is disposed may be in contact with a first surface S1 of the first redistribution substrate RS1. That is, the semiconductor chip CH1, the connection substrate 400, and the molding layer 500 may be disposed on the first surface S1 of the first redistribution substrate RS1. The first redistribution substrate RS1 may include a second surface S2 facing the first surface S1. The first redistribution substrate RS1 may include a plurality of first insulating layers 100, first redistribution patterns RDL1, a second insulating layer 200, an insulating pattern 300, first connection pads 910, second connection pads 920, and a dam structure 800. According to some example embodiments, the first insulating layers 100 may be observed as one insulating layer. In this specification, the first surface S1 of the first redistribution substrate RS1 may mean a surface of a layer disposed at the uppermost position among the first insulating layers 100 or a surface of a layer among the first insulating layers 100 that is in contact with the semiconductor chip CH1 and the connection substrate 400. The second surface S2 of the first redistribution substrate RS1 may correspond to a lower surface of the second insulating layer 200. In this specification, a first direction D1 refers to a direction parallel to the second surface S2. The second direction D2 refers to a direction parallel to the second surface S2 and perpendicular to the first direction D1. The third direction D3 refers to a direction perpendicular to the second surface S2.

Each of the first insulating layers 100 may include a photosensitive insulating material. The photosensitive insulating material may include at least one of a photosensitive polyimide, a polybenzoxazole, a phenol-based polymer, and a benzocyclobutene-based polymer. According to some example embodiments, the photosensitive insulating material may include epoxy.

The second insulating layer 200 may include a build-up film. For example, the first insulating layer 100 may be formed from an Ajinomoto build-up film (ABF). The second insulating layer 200 may include an epoxy resin and a filler. The filler may include an inorganic material such as silica or alumina. The filler may control thermal and mechanical properties of the second insulating layer 200.

The insulating pattern 300 may include a photosensitive insulating material. The photosensitive insulating material may include at least one of a photosensitive polyimide, a polybenzoxazole, a phenol-based polymer, and a benzocyclobutene-based polymer. According to some example embodiments, the photosensitive insulating material may include epoxy. For example, the insulating pattern 300 may include the same insulating material as the first insulating layer 100.

The first redistribution patterns RDL1 may be disposed in the first insulating layer 100. The first redistribution pattern RDL1 may include metal. The first connection pads 910 and the second connection pads 920 may be disposed on the second insulating layer 200. Each of the first connection pads 910 and each of the second connection pads 920 may include a via portion that penetrates the second insulating layer 200 and is in contact with the first redistribution pattern RDL1, and a pad portion that is disposed on an upper surface of the second insulating layer 200.

The first redistribution pattern RDL1 may be electrically connected to the conductive structure 420, the chip pad 10, the first connection pad 910, and the second connection pad 920 of the connection substrate 400. The first redistribution pattern RDL1 may be electrically connected to the second redistribution pattern RDL2 of a second redistribution substrate RS2, which will be described later, through the conductive structure 420 of the connection substrate 400.

The electronic element CAP may be disposed under the first connection pads 910. First connection terminals 710 may be disposed between the first connection pads 910 and the electronic element CAP. The first connection terminals 710 may include, for example, solder including tin. The electronic element CAP may include either an active component or a passive component. The electronic element CAP may be, for example, a capacitor. The electronic element CAP may be, for example, a silicon capacitor.

Second connection terminals 720 may be disposed under the second connection pads 920. The second connection terminals 720 may include, for example, solder containing tin. The second connection terminals 720 may electrically connect the first redistribution substrate RS1 to another external substrate.

The dam structure 800 may be disposed on the second insulating layer 200. The dam structure 800 may be disposed spaced apart from the electronic element CAP in the first direction D1. The underfill pattern UF may be interposed between the electronic element CAP and the first redistribution substrate RS1. The electronic element CAP may be disposed spaced apart from and may overlap the insulating pattern 300 in the third direction D3. The second redistribution substrate RS2 may be disposed on the connection substrate 400, the semiconductor chip CH1, and the molding layer 500.

The second redistribution substrate RS2 may be spaced apart from the semiconductor chip CH1 in the third direction D3 with the connection substrate 400, the semiconductor chip CH1, and the molding layer 500 interposed therebetween. The second redistribution substrate RS2 may include a third insulating layer 600 and a second redistribution pattern RDL2. The second redistribution pattern RDL2 may penetrate a portion of the molding layer 500 and be connected to the conductive structure 420 of the connection substrate 400. The third insulating layer 600 may be disposed on the second redistribution pattern RDL2. The third insulating layer 600 may include an epoxy-based compound. According to some example embodiments, the third insulating layer 600 may be formed from Ajinomoto build-up film (ABF). The third insulating layer 600 may include an upper hole OP that exposes a pad portion of the second redistribution pattern RDL2. For example, the third insulating layer 600 may define an upper hole OP therein. The second redistribution pattern RDL2 may include a metal. The second redistribution pattern RDL2 may include the same metal material as the first redistribution pattern RDL1. The exposed pad portion of the second redistribution pattern RDL2 may include a plurality of metal layers (e.g., copper, gold, nickel, etc.).

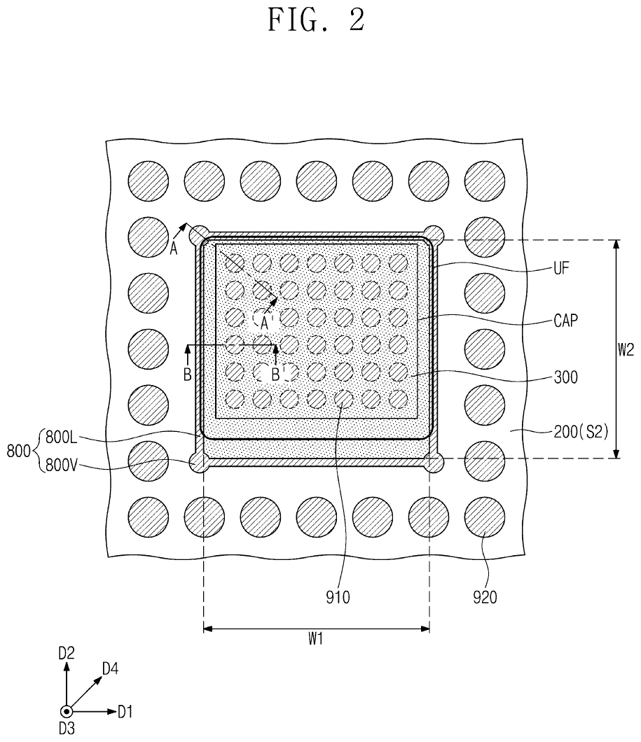

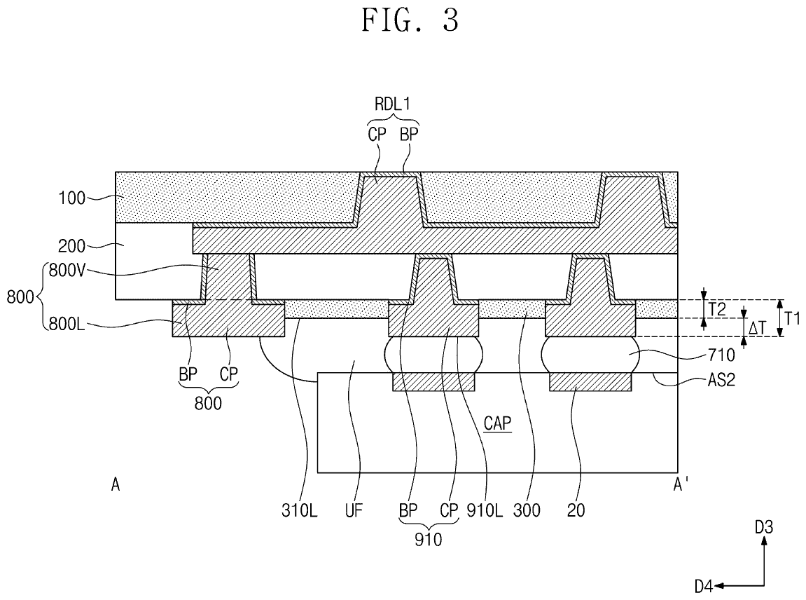

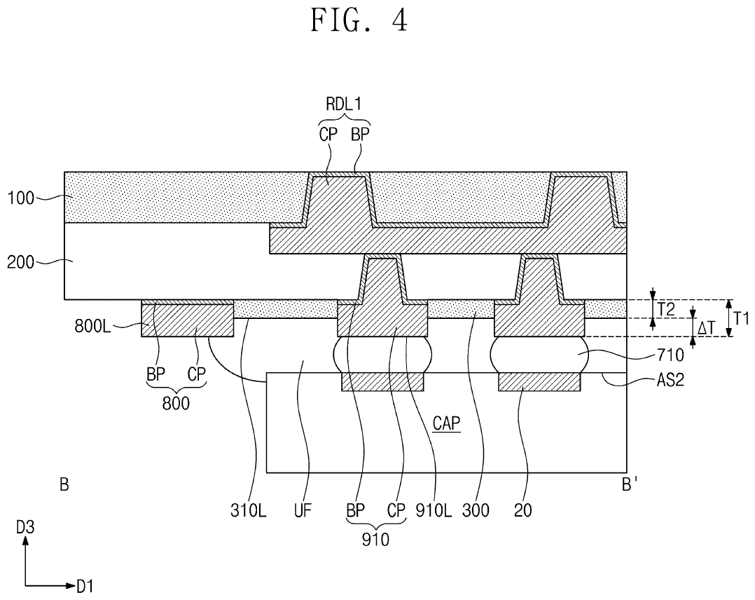

FIG. 2 is a plan view showing a lower surface of a semiconductor package according to some example embodiments of the inventive concepts. For example, FIG. 2 shows the second surface of the first redistribution substrate of FIG. 1. To clearly show the inventive concepts, the first connection terminals 710 and the second connection terminals 720 are omitted from FIG. 2. FIG. 3 is a cross-sectional view taken along line A-A′ of FIG. 2. FIG. 4 is a cross-sectional view taken along line B-B′ of FIG. 2. In the present specification, a fourth direction D4 is parallel to the second surface S2 and means one direction between the first direction D1 and the second direction D2.

Referring to FIGS. 2 to 4, the first redistribution pattern RDL1, the first connection pads 910, the second connection pads 920, and the dam structure 800 may each include a seed/barrier pattern BP and a conductive pattern CP on the seed/barrier pattern BP. The seed/barrier pattern BP may include at least one of copper, titanium, tungsten, and nickel. The conductive pattern CP may include, for example, copper. For example, the first connection pads 910, the second connection pads 920, and the dam structure 800 may all include the same metal material.

The first connection pad 910, the second connection pad 920, and the dam structure 800 may be disposed on the first redistribution pattern RDL1. The first connection pad 910, the second connection pad 920, and the dam structure 800 may be in contact with the first redistribution pattern RDL1. The first connection pads 910 may be disposed to be spaced apart from each other in the first direction D1 and the second direction D2. The second connection pads 920 may be disposed to be spaced apart from each other in the first direction D1 and the second direction D2. A diameter of each of the second connection pads 920 may be larger than a diameter of each of the first connection pads 910. The first connection pads 910 may be electrically connected to the electronic element CAP through the first connection terminals 710. The electronic element CAP may include a connection pad 20. When the electronic element CAP is a capacitor, the connection pad 20 may be an electrode. Even when the connection pad 20 is not an electrode, the connection pad 20 may be electrically connected to an electrode of the capacitor.

The underfill pattern UF may be disposed between an active surface AS2 on which the connection pad 20 of the electronic element CAP is disposed and the insulating pattern 300. The underfill pattern UF may cover a portion of a side surface of the first connection pad 910 and a side surface of the first connection terminals 710. The underfill pattern UF may cover an inner surface of the dam structure 800 on the second insulating layer 200 and may cover a portion of a side surface of the electronic element CAP. The electronic element CAP may be disposed to be centered on one side of the inner surface of the dam structure 800. According to some example embodiments, the electronic element CAP may be disposed in a center of the dam structure 800. The underfill pattern UF may be spaced apart from the second insulating layer 200. For example, the underfill pattern UF may be spaced apart from the lower surface S2 of the second insulating layer 200.

The dam structure 800 may be disposed between the first connection pads 910 and the second connection pads 920. The dam structure 800 may be spaced apart laterally from the first connection pads 910 and the second connection pads 920. The dam structure 800 may surround the first connection pads 910. The dam structure 800 may have a shape of, for example, a square ring. The dam structure 800 may include a line portion 800L and a via portion 800V. The via portion 800V may penetrate the second insulating layer 200. The via portion 800V may be in contact with the first redistribution pattern RDL1. The line portion 800L may be disposed on the second insulating layer 200. The line portion 800L may connect a plurality of via portions 800V. As described below, the dam structure 800 may limit and/or prevent the underfill pattern UF from moving to a region other than the intended region when injecting the underfill material between the insulating pattern 300 and the electronic element CAP. The dam structure 800 may be a dummy structure that is not related to a current flow.

According to some example embodiments of the inventive concepts, the second insulating layer 200 may be distinguished from the first insulating layer 100 and the insulating pattern 300 by SEM (scanning electron microscopy), TEM (transmission electron microscopy), etc. The second insulating layer 200 and the insulating pattern 300 may include different insulating materials. Even when some of the insulating materials included in the second insulating layer 200 and the insulating pattern 300 are the same, the specific compositions may be different. For example, the second insulating layer 200 may include a filler, but the insulating pattern 300 may not include a filler.

The second insulating layer 200 may have a first surface roughness, and the insulating pattern 300 may have a second surface roughness. The first surface roughness may be greater than the second surface roughness. According to some example embodiments, the second surface roughness may be less than ½ times than the first surface roughness. As described above, the first surface roughness and the second surface roughness correspond to an arithmetic average roughness (Ra), which is an absolute value of the surface roughness averaged. For example, the first surface roughness may be 0.1 μm to 0.9 μm, and the second surface roughness may be 0.01 μm to 0.05 μm. The numerical ranges of the first surface roughness and the second surface roughness may be variously changed depending on an additional surface treatment process, and are not limited thereto.

The insulating pattern 300 may be in contact with an inner surface of the line portion 800L of the dam structure 800 on the second insulating layer 200 and a side surface of the first connection pads 910. The underfill pattern UF may have better wettability on a surface of the insulating pattern 300 than on a surface of the second insulating layer 200.

The first connection pad 910 may have a first thickness T1, and the insulating pattern 300 may have a second thickness T2, both as along the third direction D3. The second thickness T2 may be smaller than the first thickness T1. A difference ΔT between the first thickness T1 and the second thickness T2 may be 1 μm or more. The difference between a level of a lower surface 910L of the first connection pad 910 and a level of a lower surface 300L of the insulating pattern 300 may also be 1 μm or more. A second thickness T2 may be 10% to 90% of the first thickness T1. For example, the first thickness T1 may be 10 μm, and the second thickness T2 may be 7 μm. The second thickness T2 may be smaller than the first thickness T1, so that a flow of the underfill material may not be impeded when the underfill material is injected. The second thickness T2 may be smaller than a thickness of the second insulating layer 200.

The insulating pattern 300 may have a first width W1 in the first direction D1 and a second width W2 in the second direction D2. The first width W1 may be larger than a width of the electronic element CAP in the first direction D1. The second width W2 may be larger than a width of the electronic element CAP in the second direction D2. The first width W1 of the insulating pattern 300 may be smaller than a width of an outer surface of the dam structure 800 in the first direction D1. The second width W2 of the insulating pattern 300 may be smaller than a width of an outer surface of the dam structure 800 in the second direction D2. For example, the planar area of the insulating pattern 300 may be larger than the planar area of the electronic element CAP and smaller than the planar area of the outer surface of the dam structure 800.

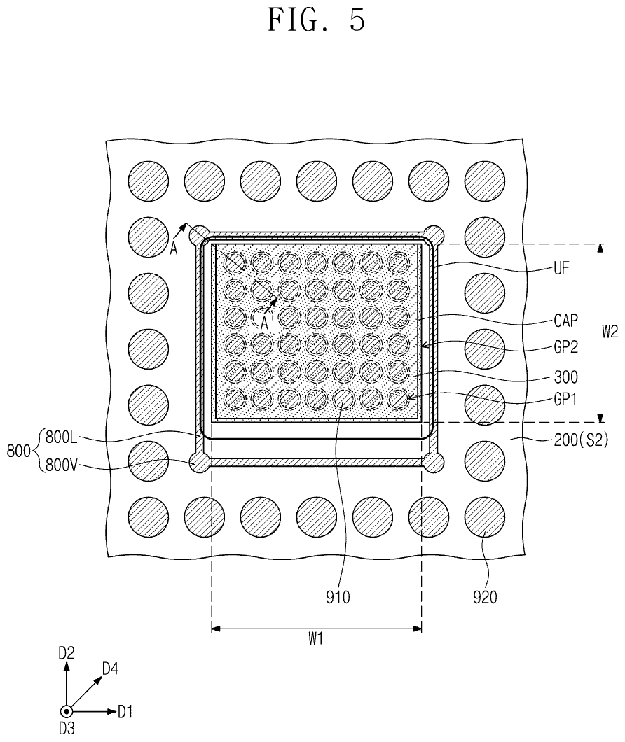

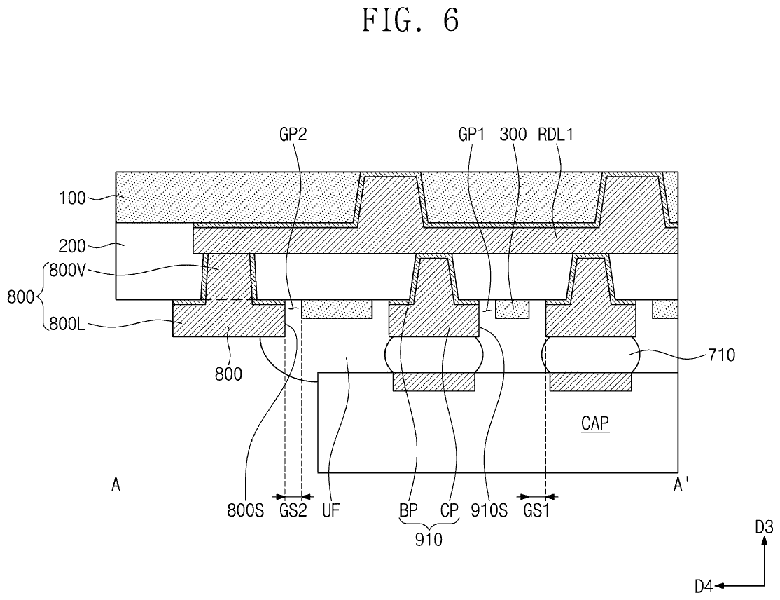

FIG. 5 is a plan view illustrating a semiconductor package according to some example embodiments of the inventive concepts. FIG. 6 is a cross-sectional view of A-A′ of FIG. 5. The overlapping content described in FIGS. 2 to 4 will be omitted from the following description.

Referring to FIGS. 5 and 6, the insulating pattern 300 may not be in contact with a side surface 910S of the first connection pad 910 and an inner surface 800S of the line portion 800L of the dam structure 800. A first gap GP1 may disposed between the insulating pattern 300 and a side surface of the first connection pad 910, and a second gap GP2 may disposed between the insulating pattern 300 and a side surface of the line portion 800L of the dam structure 800. A horizontal width GS1 of the first gap GP1 and a horizontal width GS2 of the second gap GP2 may each be 5 μm or more. For example, the horizontal width GS1 of the first gap GP1 may be 20 μm. The lower surface S2 of the second insulating layer 200 may be exposed by the first gap GP1 and the second gap GP2.

When forming the insulating pattern 300, the first gap GP1 may be adjusted to be interposed between a side surface of the first connection pad 910 and a side surface of the insulating pattern 300, and the second gap GP2 may be interposed between a side surface of the dam structure 800 and a side surface of the second connection pad 920. As a result, the first and second gaps GP1 and GP2 may limit and/or prevent the insulating pattern 300 from being formed on an upper surface of the first connection pad 910 or an upper surface of the dam structure 800 due to misalignment. For example, the first gap GP1 and the second gap GP2 may correspond to safety margins in the process. When the insulating pattern 300 is formed on the upper surface of the first connection pad 910, it may be difficult to connect the first connection pad 910 and the first connection terminal 710. When the insulating pattern 300 is formed on the upper surface of the dam structure 800, an underfill material may easily pass over an outer wall of the dam structure 800 to the outside. According to some example embodiments of the inventive concepts, the insulating pattern 300 may include the first gap GP1 and the second gap GP2, thereby limiting and/or preventing problems due to misalignment.

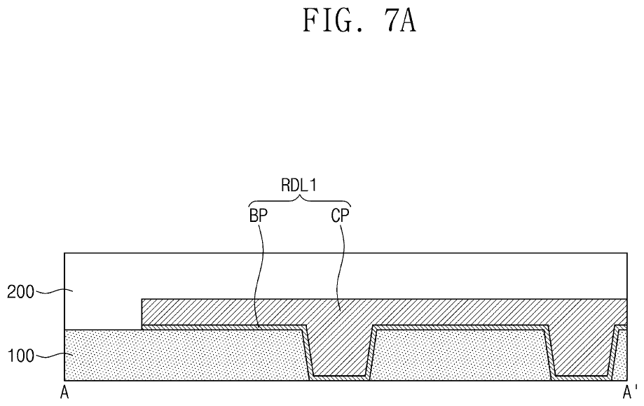

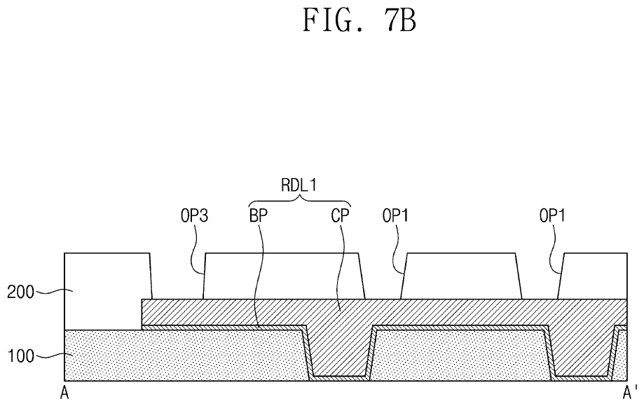

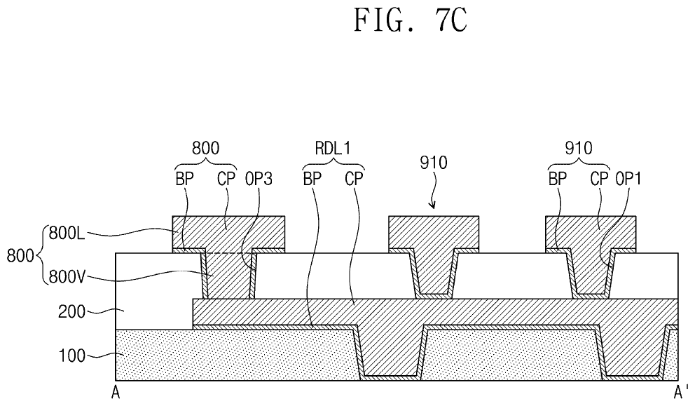

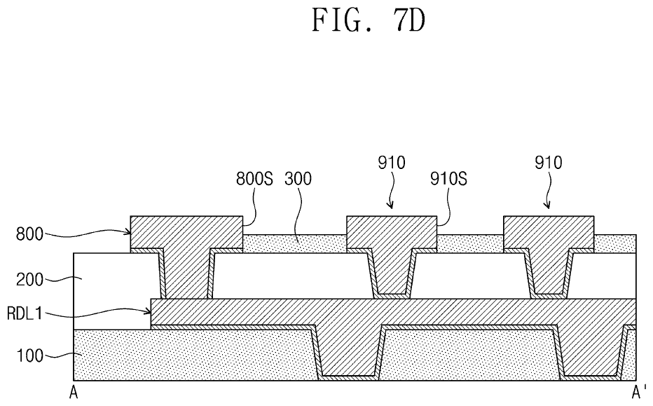

FIGS. 7A to 7D are cross-sectional views illustrating a process of manufacturing a semiconductor package according to some example embodiments of the inventive concepts. For example, FIGS. 7A to 7D are cross-sectional views corresponding to A-A′ of FIG. 5.

Referring to FIG. 7A, a first insulating layer 100 may be formed. Forming the first insulating layer 100 may include, for example, slit coating a photosensitive insulating material. After the coating, an exposure process, a development process, and a curing process may be performed to define a space where a via portion of the first redistribution pattern RDL1 is to be formed. A first redistribution pattern RDL1 may be formed on the first insulating layer 100. Forming the first redistribution pattern RDL1 may include forming a seed layer, forming a photoresist pattern defining a space where a line portion of the first redistribution pattern RDL1 is to be formed, forming a conductive pattern CP on the seed layer by electroplating, removing the photoresist pattern, and patterning the seed layer using the conductive pattern as an etching mask. A second insulating layer 200 may be formed to cover the first redistribution pattern RDL1 and the first insulating layer 100. Forming the second insulating layer 200 may include placing a build-up film (e.g., ABF) on the first redistribution pattern RDL1 and the first insulating layer 100, and thermally bonding and thermally curing the build-up film.

Referring to FIG. 7B, a first opening OP1, a second opening, and a third opening OP3 exposing the upper surface of the first redistribution pattern RDL1 may be formed on the second insulating layer 200. The first opening OP1 corresponds to a position where a via portion of the first connection pad 910 is to be formed. The second opening corresponds to a position where a via portion of the second connection pad 920 is to be formed. The third opening OP3 corresponds to a position where a via portion 800V of the dam structure 800 is to be formed. Forming the first opening OP1, the second opening, and the third opening OP3 may be, for example, an etching process using a laser. The first redistribution pattern RDL1 functions as an etch stop layer to limit and/or prevent the first insulating layer 100 from being damaged during the laser process.

Referring to FIG. 7C, a first connection pad 910, a second connection pad, and a dam structure 800 may be formed on the second insulation layer 200. For example, a seed layer may be formed on the second insulation layer 200. The seed layer may cover inner surfaces of the first opening OP1, the second opening, and the third opening OP3. Subsequently, a photoresist pattern defining a portion where a pad portion of the first connection pad 910, a pad portion of the second connection pad 920, and a line portion of the dam structure 800 are to be formed may be formed. A conductive pattern CP may be formed on the seed layer by electroplating. The photoresist pattern may be removed, and the seed layer may be patterned using the conductive pattern CP as an etching mask to form a seed/barrier pattern BP. That is, the first connection pad 910, the second connection pad, and the dam structure 800 may be formed simultaneously and may include the same metal material.

Referring to FIG. 7D, an insulating pattern 300 may be formed on the second insulating layer 200. Forming the insulating pattern 300 may include, for example, slit-coating a photosensitive insulating material on the second insulating layer 200. After the coating, exposure, development, and curing processes may be performed on the photosensitive insulating material so that the insulating pattern 300 may be provided only in an inner surface 800S of the dam structure 800. According to some example embodiments, the exposure process may be performed to have a first gap GP1 between a side surface 910S of the insulating pattern 300 and the first connection pad 910, and a second gap GP2 between the inner surface 800S of the insulating pattern 300 and the dam structure 800 (refer to FIG. 6). A thickness of the insulating pattern 300 may be adjusted to be smaller than a thickness of the first connection pad 910.

Referring again to FIG. 3, an electronic element CAP to which a first connection terminal 710 is attached may be mounted on the first connection pad 910. A second connection terminal 720 may also be attached on the second connection pad 920. Attaching the first connection terminal 710 onto the first connection pad 910 and attaching the second connection terminal 720 onto the second connection pad 920 may be performed simultaneously or at different times. Subsequently, an underfill material may be injected between the electronic element CAP and the insulating pattern 300. An underfill material injector may approach a region of an inner region of the dam structure 800 where the electronic element CAP is not mounted (refer to FIG. 2) to inject the underfill material.

The insulating pattern 300 may have lower surface roughness and good wettability with respect to the underfill material. As a result, even when the underfill material is injected in one direction, the underfill material may flow well on the upper surface of the insulating pattern 300 and may flow well to a region far from the underfill material injector. Even when the underfill material flows out of the dam structure 800, the second insulating layer 200 may have a larger surface roughness and lower wettability with respect to the underfill material. Therefore, the underfill material may not flow well on the second insulating layer 200. The underfill material may not come into contact with the side surfaces of the second connection terminals 720 and the second connection pads 920.

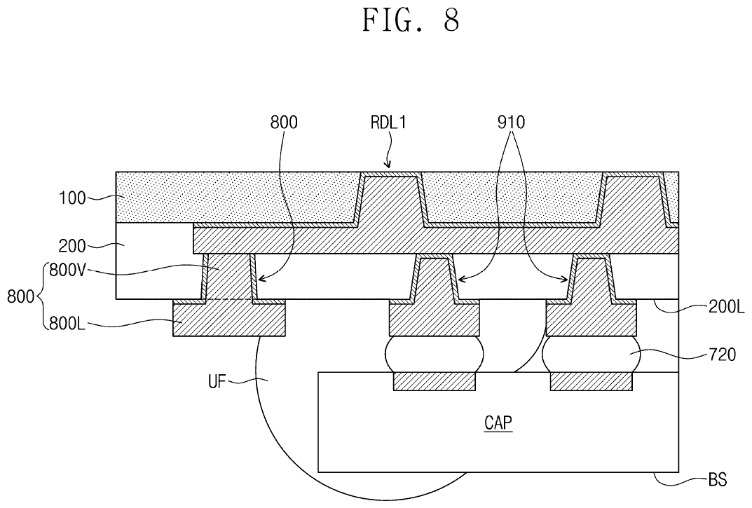

FIG. 8 illustrates a semiconductor package according to a comparative example. FIG. 8 is a cross-sectional view corresponding to A-A′ of FIG. 2.

Referring to FIG. 8, a semiconductor package according to the comparative example may not include an insulating pattern 300. Therefore, when an underfill material is injected into the inner region of the dam structure 800, the underfill material may be directly injected onto the upper surface of the second insulating layer 200. The underfill material may not flow well on a surface of the second insulating layer 200 which has high surface roughness and low wettability to the underfill material. As a result, the underfill material may not sufficiently fill between the first connection terminals. Alternatively, the underfill material may be concentrated on a region where it is injected, thereby covering an opposite surface of an active surface of the electronic element CAP.

According to the inventive concepts, the underfill material may sufficiently fill between the second connection terminals through the insulating pattern, and may sufficiently fill between the insulating pattern and the active surface of the electronic element. When the underfill material is cured to become an underfill pattern, the underfill pattern may add additional adhesive strength to the electronic element and to attaching the substrate to the redistribution substrate through the first connecting terminal. As a result, the electronic element may be limited and/or prevented from being separated from the redistribution substrate even under thermal stress and/or other physical impact, and reliability and/or durability of the semiconductor package may increase.

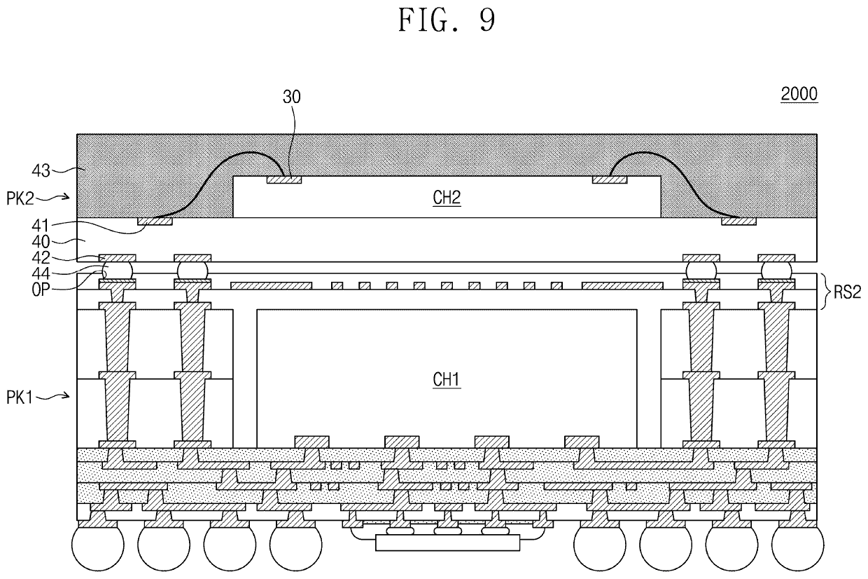

FIG. 9 is a cross-sectional view showing a semiconductor package according to some example embodiments of the inventive concepts. Hereinafter, the overlapping content with that described in FIG. 1 will be omitted and described.

Referring to FIG. 9, a semiconductor package 2000 may include a first semiconductor package PK1 and a second semiconductor package PK2. The second semiconductor package PK2 may be disposed on the first semiconductor package PK1. For example, the semiconductor package 2000 may have a package-on-package structure.

For example, the first semiconductor package PK1 may correspond to the semiconductor package 1000 described above in FIG. 1.

The second semiconductor package PK2 may include a package substrate 40, a second semiconductor chip CH2, and a second molding layer 43. The package substrate 40 may be a printed circuit board. As another example, a redistribution substrate may be used as the package substrate 40. Lower conductive pads 42 may be disposed on a lower surface of the package substrate 40, and upper conductive pads 41 may be disposed on an upper surface of the package substrate 40.

A second semiconductor chip CH2 may be disposed on the package substrate 40. The second semiconductor chip CH2 may include integrated circuits, and the integrated circuits may include memory circuits, logic circuits, or a combination thereof. The second semiconductor chip CH2 may be a different type of chip from the semiconductor chip CH1 of the first semiconductor package PK1. As an example, the semiconductor chip CH1 may be a logic chip and the second semiconductor chip CH2 may be a memory chip. Chip pads 30 of the second semiconductor chip CH2 may be electrically connected to upper conductive pads 41 on an upper surface of the package substrate 40 by bonding wire. According to some example embodiments, the second semiconductor chip CH2 may be electrically connected to the package substrate 40 by flip chip bonding instead of the bonding wire. The chip pads 30 of the second semiconductor chip CH2 may be electrically connected to the upper conductive pads 41 and lower conductive pads 42 through internal wiring in the package substrate 40. The second molding layer 43 may be provided on the package substrate 40 to cover the second semiconductor chip CH2. The second molding layer 43 may include an insulating polymer such as an epoxy polymer.

Package connection terminals 44 may be provided in upper holes OP of the molding layer 500 of the first semiconductor package PK1. The package connection terminals 44 may be in contact with the conductive structures 420 and the lower conductive pad 42.

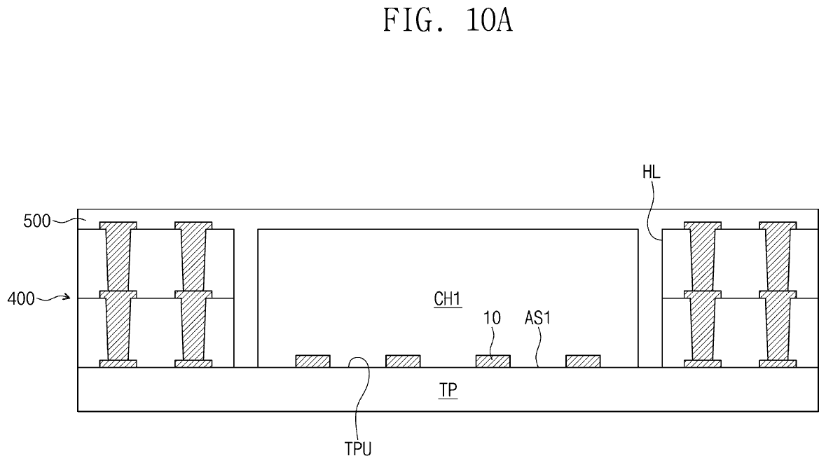

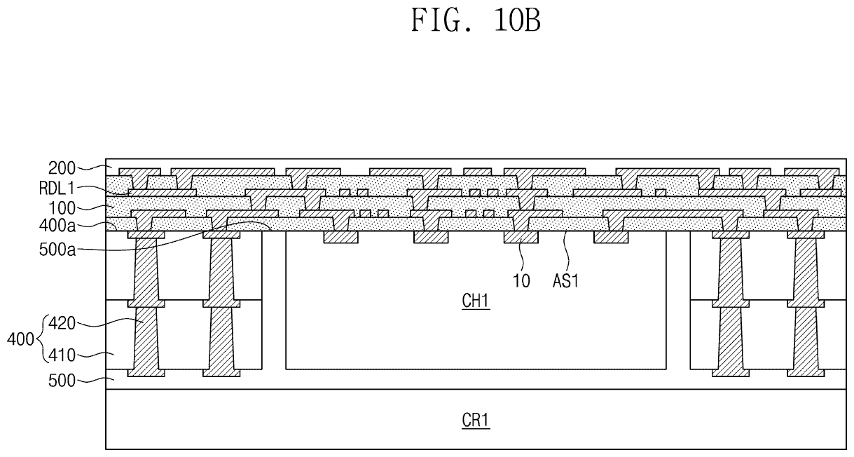

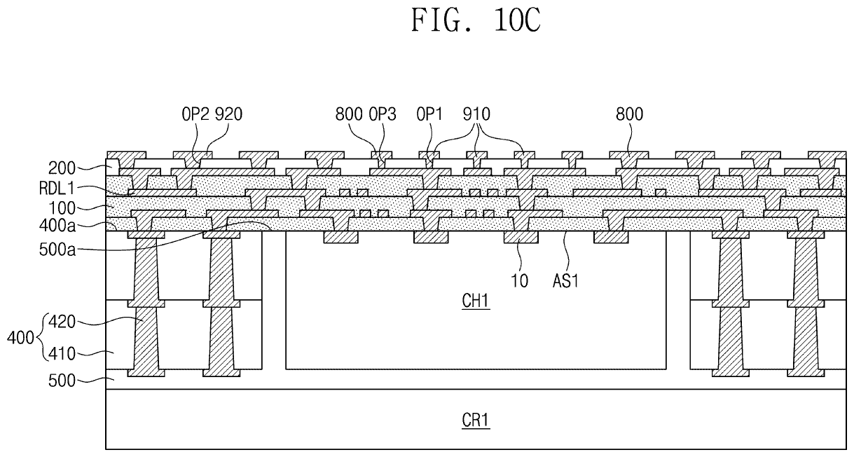

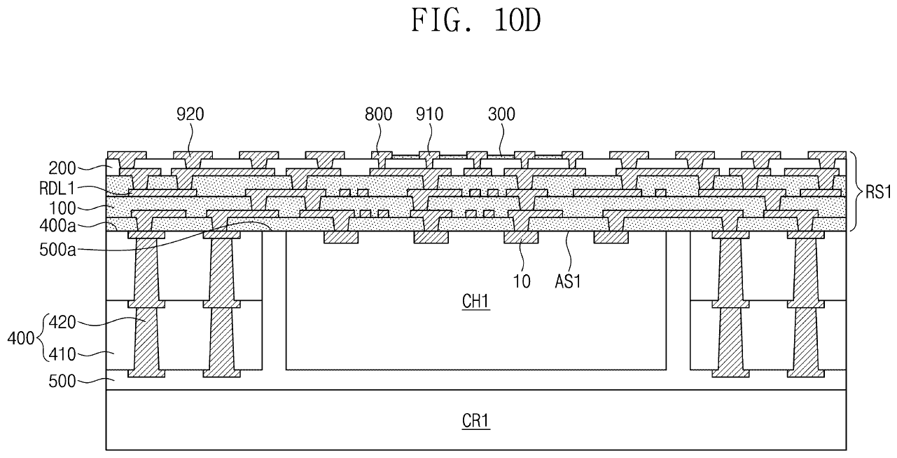

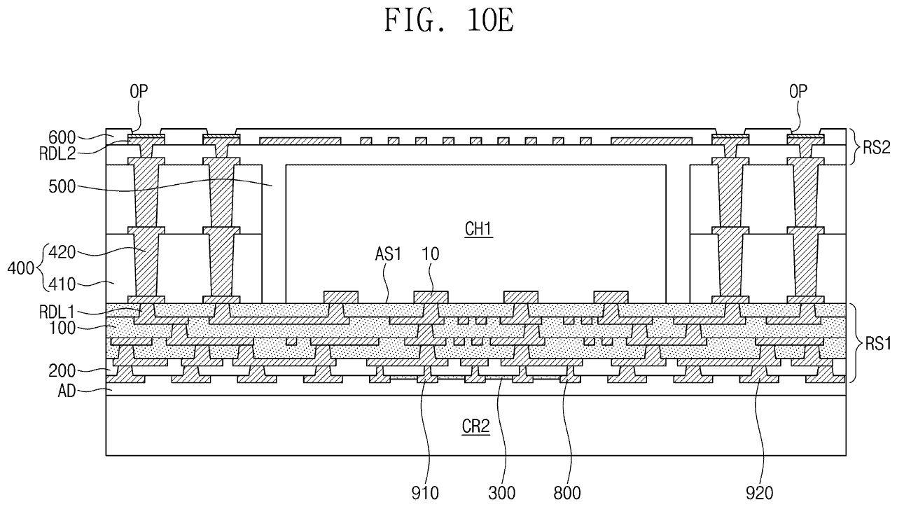

FIGS. 10A to 10E are cross-sectional views illustrating a process for manufacturing a semiconductor package according to some example embodiments of the inventive concepts.

Referring to FIG. 10A, a connection substrate 400 may be prepared. For example, a hole HL may be formed in a printed circuit board (PCB) and used as a connection substrate 400. For example, the hole HL of the connection substrate 400 may be formed using a laser.

The connection substrate 400 may be disposed on an upper surface TPU of a temporary tape TP. The connection substrate 400 may be directly attached to the upper surface TPU of the temporary tape TP. The temporary tape TP may include an insulating polymer such as, for example, polyimide. The temporary tape TP may be an adhesive tape.

A semiconductor chip CH1 may be disposed in the hole HL of the connection substrate 400. The semiconductor chip CH1 may be disposed on the upper surface TPU of the temporary tape TP. An active surface AS1 of the semiconductor chip CH1 may be in physical contact with the upper surface TPU of the temporary tape TP.

A molding layer 500 covering an upper surface and an inner surface of the connection substrate 400 and a side surface and an upper surface of the semiconductor chip CH1 may be formed. Forming the molding layer 500 may include attaching an adhesive insulating layer on the upper surface of the connection substrate 400 and the upper surface of the semiconductor chip CH1. For example, an Ajinomoto build-up film (ABF) may be used as the adhesive insulating layer. The molding layer 500 may extend into a gap region between the connection substrate 400 and the semiconductor chip CH1 and may be in contact with the upper surface of the temporary tape TP. For example, a lower surface of the molding layer 500 may be in physical contact with the upper surface TPU of the temporary tape TP.

Referring to FIG. 10B, a first carrier substrate CR1 may be disposed on the molding layer 500. A first carrier adhesive layer (not shown) may be further interposed between the first carrier substrate CR1 and the molding layer 500. The temporary tape TP may be removed, so that one surface 400a of the connection substrate 400, an active surface AS1 of the semiconductor chip CH1, and one surface 500a of the molding layer 500 may be exposed. The first insulating layers 100 and the first redistribution pattern RDL1 may be formed on the exposed one surface 400a of the connection substrate 400, the one surface 500a of the molding layer 500, and the active surface AS1 of the semiconductor chip CH1.

A second insulating layer 200 may be formed on the uppermost first redistribution pattern RDL1 among the first redistribution patterns RDL1. Forming the second insulating layer 200 may include attaching an adhesive insulating layer on an upper surface of the first insulating layer 100 and an upper surface of the first redistribution pattern RDL1. The adhesive insulating layer may be, for example, an Ajinomoto Build-up film (ABF). Forming the first redistribution patterns RDL1 and the second insulating layer 200 may be performed in substantially the same manner as described in FIG. 7A.

Referring to FIG. 10C, a process of exposing the upper surface of the uppermost first redistribution pattern RDL1 may be performed. For example, a first opening OP1, a second opening OP2, and a third opening OP3 may be formed in the second insulating layer 200. The process of forming the first opening OP1, the second opening OP2, and the third opening OP3 may be substantially the same as the process described in FIG. 7B. Next, the first connection pads 910, the second connection pads 920, and the dam structure 800 may be formed on the first redistribution pattern RDL1. The forming of the first connection pads 910, the second connection pads 920, and the dam structure 800 may be substantially the same as the method described in FIG. 7C above.

Referring to FIG. 10D, an insulating pattern 300 may be formed on the second insulating layer 200. The forming of the insulating pattern 300 may be substantially the same as the method described in FIG. 7D above. By forming the insulating pattern 300, the first redistribution substrate RS1 may be formed.

Referring to FIG. 10E, the first carrier substrate CR1 may be removed. A second carrier substrate CR2 may be disposed on the second insulating layer 200, the insulating pattern 300, the first connection pad 910, the second connection pad 920, and the dam structure 800. A second carrier adhesive layer AD may be interposed between the second carrier substrate CR2 and the first redistribution substrate RS1. The second carrier adhesive layer AD may include an adhesive insulating layer, for example, an Ajinomoto build-up film (ABF). The second carrier adhesive layer AD may include an insulating material that is the same as or similar to the second insulating layer 200.

A second redistribution pattern RDL2 electrically connected to the conductive structure 420 of the connection substrate 400 may be formed on the connection substrate 400 and the molding layer 500. The second redistribution pattern RDL2 may be formed in the same or similar manner as the first redistribution pattern RDL1 is formed. Subsequently, a third insulating layer 600 covering the second redistribution pattern RDL2, the connection substrate 400, and the molding layer 500 may be formed. For example, the third insulating layer 600 may include an insulating adhesive layer and may be formed from, for example, an Ajinomoto Build-up film (ABF). Subsequently, an upper hole OP exposing a pad portion of the second redistribution pattern RDL2 may be formed. The upper hole OP may be formed using, for example, a laser. As a result, the second redistribution substrate RS2 may be formed.

Referring again to FIG. 1, the second carrier substrate CR2 and the second carrier adhesive layer AD may be removed. The first connection pad 910, the second connection pad 920, and the dam structure 800 may be exposed. An electronic element CAP having a first connection terminal 710 attached thereto may be mounted on the first connection pad 910, and a second connection terminal 720 may be formed on the second connection pad 920. An underfill material may be injected to form an underfill pattern UF. Mounting the electronic element CAP, forming the second connection terminal 720, and forming the underfill pattern UF may be substantially the same as the manufacturing process described above in FIG. 3. As a result, the semiconductor package 1000 of FIG. 1 may be formed.

Referring to FIG. 9, a second semiconductor package PK2 may be disposed on the semiconductor package 1000 to form a semiconductor package 2000 having a package-on-package structure.

According to the inventive concepts, when the semiconductor package mounts the electronic element on the lower surface of the redistribution substrate, the insulating pattern may be disposed in the portion that comes into contact with the underfill pattern. The insulating pattern may include the photosensitive material and may have the small surface roughness. As the wettability between the underfill material and the insulating pattern is improved, the underfill material may flow well onto the surface of the insulating pattern. The underfill material may be hardened to properly fix the electronic element when the underfill pattern is formed. As a result, the reliability and/or durability of the semiconductor package may be increased.

While some example embodiments are described above, a person skilled in the art may understand that many modifications and variations are made without departing from the spirit and scope of the inventive concepts defined in the following claims. Accordingly, the example embodiments of the inventive concepts should be considered in all respects as illustrative and not restrictive, with the spirit and scope of the inventive concepts being indicated by the appended claims.

What is claimed is:

1. A semiconductor package comprising:
a first redistribution substrate including a first surface and a second surface facing the first surface;
a semiconductor chip on the first surface;
an electronic element on the second surface; and
an underfill pattern between the electronic element and the second surface,
wherein the first redistribution substrate includes
a first insulating layer, and
an insulating pattern and a dam structure both on the first insulating layer,
wherein the dam structure is spaced apart from the electronic element in a first direction parallel to the second surface,
wherein the insulating pattern includes an insulating material different than an insulating material of the first insulating layer, and
wherein the insulating pattern is in contact with the first insulating layer and the underfill pattern.

2. The semiconductor package of claim 1, wherein the underfill pattern is spaced apart from the first insulating layer.

3. The semiconductor package of claim 1, wherein
the first insulating layer includes a build-up film, and
the insulating pattern includes a photosensitive insulating material.

4. The semiconductor package of claim 1, wherein
the insulating pattern has a first width in the first direction,
the electronic element has a second width in the first direction,
the dam structure has a third width in the first direction, and
the first width is larger than the second width and smaller than the third width.

5. The semiconductor package of claim 1, wherein the first redistribution substrate further includes:
connection pads on the first insulating layer; and
connection terminals connecting the connection pads and the electronic element, and
wherein the insulating pattern is between side surfaces of the connection pads.

6. The semiconductor package of claim 5, wherein
each of the connection pads has a first thickness in a second direction perpendicular to the second surface, the first thickness being from a lower surface of the first insulating layer,
the insulating pattern has a second thickness in the second direction perpendicular to the second surface, the second thickness being from the lower surface of the first insulating layer, and
the second thickness is smaller than the first thickness.

7. The semiconductor package of claim 6, wherein the second thickness is at least 1 μm smaller than the first thickness.

8. The semiconductor package of claim 6, wherein the second thickness is 10% to 90% of the first thickness.

9. The semiconductor package of claim 5, wherein the insulating pattern is in contact with the side surfaces of the connection pads.

10. The semiconductor package of claim 5, wherein
the insulating pattern is spaced apart from each of the side surfaces of the connection pads, and
the first insulating layer is exposed at gaps between the insulating pattern and the connection pads.

11. The semiconductor package of claim 10, wherein
the gaps have a first width in the first direction, and
the first width is 5 μm or more.

12. The semiconductor package of claim 5, wherein the dam structure surrounds the connection pads.

13. The semiconductor package of claim 1, wherein a thickness of the insulating pattern is smaller than a thickness of the first insulating layer.

14. The semiconductor package of claim 1, wherein the electronic element includes a silicon capacitor.

15. A semiconductor package comprising:
a redistribution substrate including a first surface and a second surface facing the first surface;
a semiconductor chip on the first surface;
an electronic element on the second surface; and
an underfill pattern between the electronic element and the second surface,
wherein the redistribution substrate includes
a first insulating layer,
a redistribution pattern in the first insulating layer,
a second insulating layer on the first insulating layer and the redistribution pattern, and
an insulating pattern on the second insulating layer,
wherein the electronic element overlaps the insulating pattern in a vertical direction,
wherein the second insulating layer has a first surface roughness,
wherein the insulating pattern has a second surface roughness,
wherein the second surface roughness is lower than the first surface roughness, and
wherein the underfill pattern is in contact with the insulating pattern.

16. The semiconductor package of claim 15, wherein
the first surface roughness is 0.1 μm to 0.9 μm, and
the second surface roughness is 0.01 μm to 0.05 μm.

17. The semiconductor package of claim 15, wherein
the redistribution substrate further comprises a dam structure on the second insulating layer, and
the dam structure surrounds the insulating pattern.

18. The semiconductor package of claim 17, wherein the dam structure further includes:
a plurality of via portions penetrating the second insulating layer; and
line portions on the second insulating layer connecting the via portions.

19. The semiconductor package of claim 17, wherein the redistribution substrate further includes:
a connection pad penetrating the second insulating layer and connected to the redistribution pattern; and
a connection terminal between the connection pad and the electronic element, and wherein the connection pad and the dam structure include a same metal material.

20. A semiconductor package comprising:
a first redistribution substrate including a first surface and a second surface facing the first surface;
a connection substrate on the first surface, the connection substrate defining a hole therein;
a semiconductor chip in the hole;
a molding layer filling the hole and covering the semiconductor chip;
a capacitor on the second surface;
an underfill pattern between the capacitor and the second surface; and
a second redistribution substrate on the molding layer and the connection substrate,
wherein the first redistribution substrate includes
a first insulating layer,
a redistribution pattern in the first insulating layer,
a second insulating layer on the first insulating layer and the redistribution pattern,
connection pads and an insulating pattern both on the second insulating layer, and
a dam structure surrounding the connection pads and the insulating pattern,
wherein the insulating pattern is between the connection pads,
wherein the insulating pattern includes an insulating material different than an insulating material of the second insulating layer,
wherein the insulating pattern includes a photosensitive insulating material, and
wherein the underfill pattern is in contact with the insulating pattern.
